(19) United States
(12) Patent Application Publication
(10) Pub. No.: US 2011/0294010 A1
(43) Pub. Date: Dec. 1, 2011

(54) POWER STORAGE DEVICE AND MANUFACTURING METHOD THEREOF

(75) Inventor: Mikio YUKAWA, Atsugi (JP)

(73) Assignee: SEMICONDUCTOR ENERGY LABORATORY CO., LTD., Atsugi-shi (JP)

(21) Appl. No.: 13/113,237

(22) Filed: May 23, 2011

(30) Foreign Application Priority Data
May 28, 2010 (JP) 2010-122907

(51) Int. Cl. H01M 4/66; H01G 9/15; C23C 16/44; C23C 14/34; C23C 14/08

(52) U.S. Cl. 429/211; 427/576; 361/523

(57) ABSTRACT

It is an object to perform insertion and extraction of lithium ions effectively at a positive electrode of a power storage device so as to increase the reaction speed. Further, it is an object to increase the capacitance per unit volume of an active material of a positive electrode. A layer containing carbon and an active material layer are stacked at a positive electrode, whereby insertion and extraction of lithium ions are effectively performed at the positive electrode and reaction speed can be increased, even when the thickness of the positive electrode is increased. The active material layer interposed between the layers each containing carbon includes particulate crystals and therefore has high density, so that the active material can have large capacitance per unit volume.

### BACKGROUND OF THE INVENTION

1. Field of the Invention

The present invention relates to a manufacturing method of a positive electrode of a power storage device and a manufacturing method of a power storage device. In particular, the present invention relates to a manufacturing method of a positive electrode of a lithium ion battery (a lithium ion secondary battery) or a lithium ion capacitor as a power storage device.

2. Description of the Related Art

The field of portable electronic devices such as personal computers and cellular phones has progressed significantly. The portable electronic device needs a chargeable power storage device having high energy density, which is small, lightweight, and reliable. As such a power storage device, for example, a lithium ion secondary battery (alternatively called a lithium ion storage battery or simply a lithium ion battery) is known (see Patent Document 1). In addition, development of electrically propelled vehicles on which secondary batteries are mounted has also been progressing rapidly from a rise of growing awareness to environmental problems and energy problems.

A secondary battery and an electric double layer capacitor have a structure in which an electrolyte is provided between a positive electrode and a negative electrode. It is known that each of the positive electrode and negative electrode includes a current collector and an active material provided over the current collector. For example, in a lithium ion battery, a material capable of absorbing and releasing lithium ions is used for a positive electrode as an active material, and an electrolyte is interposed between electrodes.

It is necessary for the active material used for the positive electrode to use a material which is not easily oxidized. Accordingly, oxide is often used because oxide is not oxidized anymore. However, since oxide has generally high resistance, insertion and extraction of lithium ions are not effectively performed in the active material even with application of voltage, and thus reaction speed becomes low. When the amount of a conduction auxiliary agent is increased in order to improve the reaction speed, the capacitance per unit volume of the active material is decreased. Moreover, when a film thickness of the active material is increased, transfer of lithium ions is inhibited and the capacitance thereof is decreased.

### REFERENCE

### Patent Document

[Patent Document 1] Japanese Published Patent Application No. H9-35714

### SUMMARY OF THE INVENTION

It is an object of one embodiment of the present invention to provide a power storage device with large capacitance in which lithium ions react at high speed.

It is another object of one embodiment of the present invention to provide a positive electrode or a power storage device having favorable battery characteristics.

The present inventor has found that when layers each containing carbon and an active material layer are stacked in a positive electrode, insertion and extraction of lithium ions are effectively performed at the positive electrode even when the thickness of the positive electrode is increased.

The active material layer interposed between the layers each containing carbon includes particulate crystals and therefore has high density, so that the active material can have large capacitance per unit volume.

One embodiment of the present invention is that a power storage device includes, over a current collector, a positive electrode in which a layer containing carbon and an active material layer including particulate crystals are stacked n times (n is a natural number more than or equal to 2) in this order. The active material layer contains lithium metal oxide.

One embodiment of the present invention is that a power storage device includes, over a current collector, a positive electrode in which a layer containing carbon and an active material layer including particulate crystals are stacked n times in this order and a (n+1)th layer containing carbon is stacked over the active material layers stacked n times. The active material layer contains lithium metal oxide.

One embodiment of the present invention is that a power storage device includes, over a current collector, a positive electrode in which an active material layer including particulate crystals and a layer containing carbon are stacked n times in this order. The active material layer contains lithium metal oxide.

In one embodiment of the present invention, n is more than or equal to 2 and less than or equal to 10.

In one embodiment of the present invention, the lithium metal oxide is any one of LiFePO₄, LiMnPO₄, LiNiPO₄, and LiCrPO₄.

According to one embodiment of the present invention, a power storage device whose capacitance as a battery is increased can be provided. Further, according to one embodiment of the present invention, a power storage device in which lithium ions react at high speed at a positive electrode can be provided. In addition, according to one embodiment of the present invention, a positive electrode or a power storage device having favorable battery characteristics can be provided.

### BRIEF DESCRIPTION OF THE DRAWINGS

FIG. 1 is a cross-sectional view of a positive electrode of a power storage device.

FIGS. 2A to 2E illustrate an example of a method for manufacturing a positive electrode of a power storage device.

FIG. 3 illustrates an example of a battery which is one embodiment of the present invention.

FIG. 4 illustrates an example of a cross section of a battery which is one embodiment of the present invention.

FIG. 5 is a diagram showing configurations of a wireless power feeding system.

FIG. 6 is a diagram showing configurations of a wireless power feeding system.

### DETAILED DESCRIPTION OF THE INVENTION

Embodiments of the invention disclosed in this specification will be hereinafter described with reference to the accompanying drawings. Note that the invention disclosed in this specification can be carried out in a variety of different modes, and it is easily understood by those skilled in the art that the modes and details of the invention disclosed in this specification can be changed in various ways without departing from the spirit and scope thereof. Therefore, the present invention is not construed as being limited to description of the embodiments. Note that, in the drawings hereinafter shown, the same portions or portions having similar functions are denoted by the same reference numerals, and repeated description thereof will be omitted.

### Embodiment 1

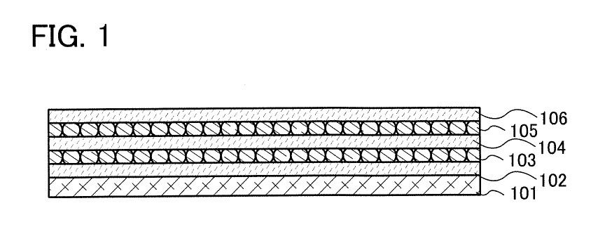

In this embodiment, a positive electrode which is one embodiment of the present invention will be described with reference to FIG. 1.

The positive electrode in FIG. 1 includes a layer 102 containing carbon and an active material layer 103 including particulate crystals over a current collector 101. The layer 102 containing carbon is provided so that reaction between the current collector 101 and the active material layer 103 can be suppressed. Alternatively, the active material layer 103 may be stacked on the current collector 101, in which case adhesion at an interface therebetween is increased and separation can be prevented because the current collector and the active material layer are both inorganic materials.

Further, a layer 104 containing carbon and an active material layer 105 including particulate crystals are stacked over the active material layer 103 in this order (hereinafter, stacking of one layer containing carbon and one active material layer is referred to as one stacking). FIG. 1 illustrates a structure in which two layers each containing carbon and two active material layers are stacked, that is, stacking is performed twice; however, stacking may be performed plural times as needed without being limited to this structure. The number of stacking, which is determined in accordance with the desired capacitance of a secondary battery and the property of the active material, is twice or more, preferably more than or equal to twice and less than or equal to ten times.

The thickness of one layer containing carbon is greater than 0 nm and less than or equal to 100 nm, preferably 2 nm to 10 nm. The thickness of one active material layer is greater than 0 nm and less than or equal to 100 nm, preferably 40 nm to 50 nm. However, optimal values may be selected as appropriate because the property of each layer varies depending on its material and shape. The total thickness of the layers each containing carbon and the active material layers is 20 nm to 1 μm, preferably 200 nm to 400 nm.

Next, a layer 106 containing carbon is stacked. The layer 106 containing carbon is provided so as to cover a surface of the active material layer 105, and thus can also function as a protective film that prevents oxidation of the active material layer 105. Note that a structure without the layer 106 containing carbon, in which layers up to and including the active material layer 105 which is the uppermost layer among the active material layers are formed, may be used as a positive electrode.

In the positive electrode, layers each containing carbon and active material layers are stacked, so that conductivities of respective surfaces of the active material layers can be increased. The active material layers each having high resistance are positioned with carbon having low resistance provided therebetween, whereby the active materials can be electrically connected to each other easily and the conductivity of the whole positive electrode can be increased. Therefore, insertion and extraction of lithium ions are effectively performed in the positive electrode, and the capacitance of the power storage device can be increased.

The active material layer including particulate crystals has high density, so that the amount of active materials per unit volume can be large. In addition, since the active material includes particulate crystals, lithium ions can be easily inserted and extracted, whereby rate characteristics of the secondary battery are improved and charging can be performed in a short time.

With the use of the structure in one embodiment of this invention, a positive electrode or a power storage device with large capacitance and favorable battery characteristics can be provided.

### Embodiment 2

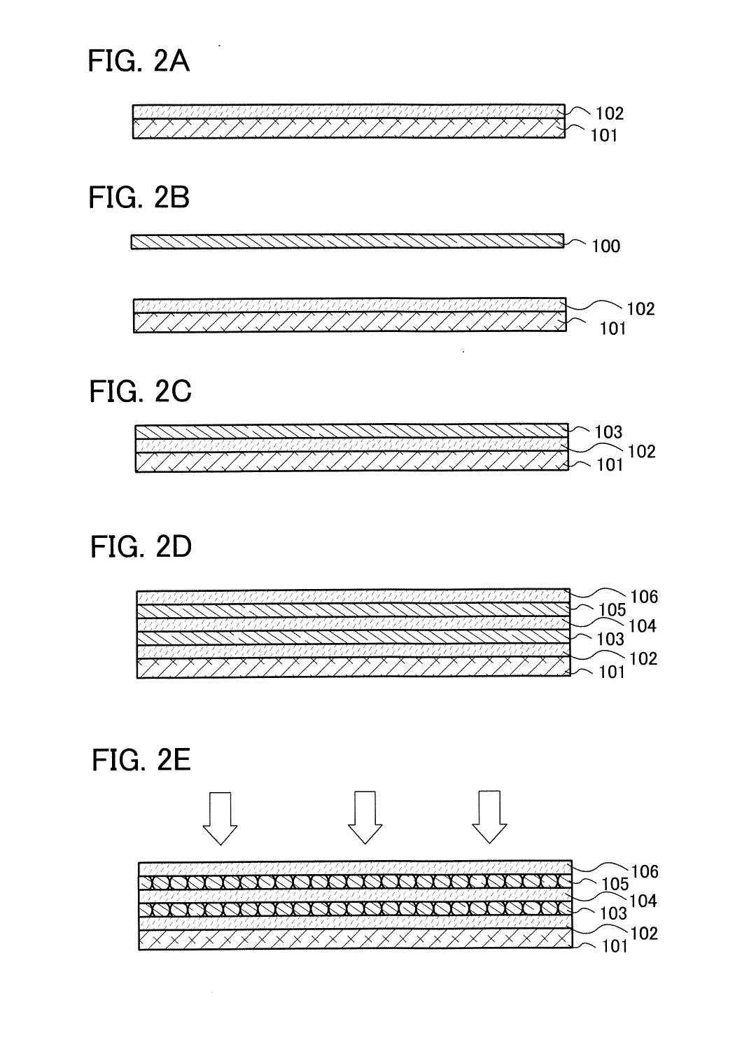

In this embodiment, a method for manufacturing a positive electrode which is one embodiment of the present invention will be described with reference to FIGS. 2A to 2E.

The layer 102 containing carbon is formed over the current collector 101 (see FIG. 2A). A material having high conductivity such as titanium is used for the current collector 101. As a method for forming the layer containing carbon, a substance containing carbon, such as pyrene, graphite, activated carbon, or phthalocyanine, may be evaporated. As an evaporation method, a vacuum evaporation method, an evaporation method using resistance heating, or the like is used. Alternatively, a polymer such as polyaniline or a ketone in a liquid state such as acetone may be formed by a coating method, an inkjet method, a spin coating method, a dip coating method, or the like.

The active material layer 103 is obtained by a sputtering method. For example, the active material layer 103 is formed using a thin film of lithium oxide such as LiₓFe_{y}(PO₄)_{z}, LiₓMn_{y}(PO₄)_{z}, LiₓNi_{y}(PO₄)_{z}, or LiₓCr_{y}(PO₄)_{z} (x, y, and z are positive real numbers).

In this embodiment, the case of forming LiFePO₄ will be described. A target 100 including at least Fe, Li, and PO₄ is used, and the target 100 is sputtered with ions of a rare gas or the like, whereby the active material layer 103 is formed over the layer 102 containing carbon (see FIGS. 2B and 2C).

As an example of the composition of a material for forming the target 100, a general formula LiₓFe_{y}(PO₄)_{z} can be given; specifically, Li₃Fe₂(PO₄)₃ can be given. The material for forming the target 100 may be a composite material, and a mixture of Li₃Fe₂(PO₄)₃ and Fe₂O₃ is given as an example. Lithium iron phosphate having a NASICON structure is preferably used for the target 100. Thus, the active material layer can be formed using an inexpensive, stable target.

As the sputtering method, an RF sputtering method using a high-frequency power source, a DC sputtering method using a direct-current power source, a pulsed DC sputtering method in which a direct-current bias is applied in a pulsed manner, or the like can be used.

As a sputtering gas, a rare gas, oxygen, a mixed gas of a rare gas and oxygen, or the like can be used. As the rare gas, argon or the like can be given.

Further, the layer 104 containing carbon is formed over the active material layer 103. As a method for forming the layer 104 containing carbon, a substance containing carbon, such as pyrene, graphite, activated carbon, or phthalocyanine, may be evaporated, as in the formation of the layer 102 containing carbon. Alternatively, a polymer such as polyaniline or a ketone in a liquid state such as acetone may be applied to form the layer 104 containing carbon.

Then, the active material layer 105 is formed. In such a manner, an active material layer and a layer containing carbon are stacked n times (twice in FIGS. 2A to 2E). Note that the n may be determined in accordance with the desired property of the power storage device.

After a film thickness enough for securing sufficient capacitance is reached, the layer 106 containing carbon is stacked over an active material layer which is stacked at the top (the active material layer 105 in FIGS. 2A to 2E) so as to become the uppermost layer. The layer 106 containing carbon also functions as a protective film that prevents oxidation of the active material layer 105 (see FIG. 2D).

Next, heat treatment is performed (FIG. 2E). The heat treatment may be performed at a temperature higher than or equal to 400° C. and lower than or equal to 1000° C., preferably higher than or equal to 500° C. and lower than or equal to 600° C., for greater than or equal to one hour and less than or equal to ten hours, preferably approximately five hours.

By the heat treatment, the active material layer is crystallized into particles. The active material is crystallized into particles, so that the density of the active material layer is increased and the capacitance per unit volume is increased. Further, lithium ions can be easily inserted and extracted, whereby rate characteristics of the secondary battery are improved and charging can be performed in a short time.

With the use of the positive electrode described in this embodiment, a power storage device with large capacitance and excellent characteristics can be obtained.

### Embodiment 3

In this embodiment, a battery which is one embodiment of the present invention and a manufacturing method thereof will be described. As a positive electrode of the battery, the positive electrode described in Embodiments 1 and 2 is used.

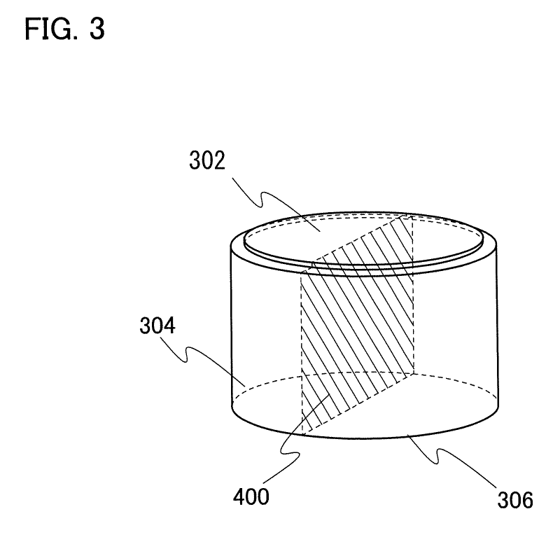

FIG. 3 is a perspective view schematically illustrating an example of a cylindrical storage battery which is one embodiment of the present invention. Note that the present invention is not limited thereto and the storage battery may be angular.

The cylindrical storage battery in FIG. 3 has a closed space surrounded by a battery sidewall 304, a battery cover 302, and a battery bottom 306.

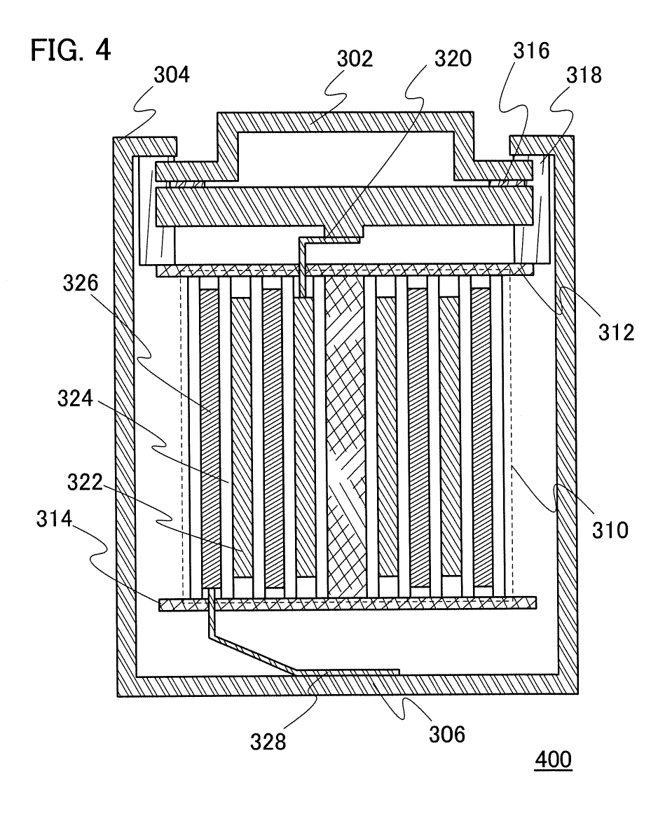

FIG. 4 is a cross-sectional view taken along a cross section 400 of the cylindrical storage battery in FIG. 3.

The battery sidewall 304 and the battery bottom 306 may be formed using a conductive material and an appropriate material may be selected so that the battery sidewall 304 and the battery bottom 306 have appropriate mechanical strength and chemical resistance under the usage environment of the storage battery. For example, an aluminum alloy can be used. The closed space is formed inside the battery surrounded by the battery sidewall 304, the battery bottom 306, and the battery cover 302. An electrode body 310 is placed in the closed space, for example. As an example of the electrode body, a wound electrode body illustrated in FIG. 3 can be given.

The electrode body 310 is sandwiched between an insulating plate 312 on an upper portion (the battery cover 302 side) and an insulating plate 314 on a lower portion (the battery bottom 306 side). A conductive wiring 320 and a conductive wiring 328 are drawn out from the insulating plate 312 and the insulating plate 314, respectively. It is preferable that the conductive wiring 320 drawn out from the insulating plate 312 of the upper portion (the battery cover 302 side) be connected to the battery cover 302 through a resistor 316. As the resistor 316, a heat sensitive resistor whose resistance increases as a temperature rises is preferably used. This is for prevention of abnormal heat generation due to excessive current flow. The conductive wiring 328 drawn out from the insulating plate 314 of the lower portion (the battery bottom 306 side) is connected to the battery bottom 306. Note that the battery bottom 306 and the battery sidewall 304 are electrically connected to each other.

The battery sidewall 304, the battery cover 302, and the insulating plate 312 of the upper portion (the battery cover 302 side) are preferably connected to each other through a gasket 318. The gasket 318 preferably has an insulating property; however, there is no limitation thereto and any gasket can be used as long as the battery cover 302 and the battery sidewall 304 are insulated from each other.

Although not illustrated, a structure may be employed in which a safety valve is provided inside the battery so that the connection between the battery cover 302 and the electrode body 310 is cut off in the case where a negative electrode 326 and a positive electrode 322 are short-circuited or the battery is heated and the pressure in the battery increases.

Further, a center pin may be inserted in the center of the electrode body 310 in order to fix a position of the electrode body 310.

The electrode body 310 includes the negative electrode 326, the positive electrode 322, and a separator 324 provided therebetween. The positive electrode 322 included in the electrode body 310 is electrically connected to the battery cover 302 through the conductive wiring 320. The negative electrode 326 included in the electrode body 310 is electrically connected to the battery bottom 306 through the conductive wiring 328.

As the positive electrode, the positive electrode described in Embodiments 1 and 2 is used. The negative electrode 326 is preferably formed using a current collector and an active material. For example, graphite or silicon serving as a negative electrode active material may be formed over a negative electrode current collector.

A negative electrode active material layer may be formed by mixing the negative electrode active material with a conduction auxiliary agent, a binder, or the like and processed into a paste which is then applied onto a current collector. Alternatively, the negative electrode active material layer may be formed by a sputtering method. The negative electrode active material layer may be molded as needed by applying pressure.

Note that titanium, copper, or the like can be used for the current collector.

As the separator 324, paper, nonwoven fabric, a glass fiber, a synthetic fiber such as nylon (polyamide), vinylon (also called vinalon) (a polyvinyl alcohol based fiber), polyester, acrylic, polyolefin, or polyurethane, or the like can be used. However, a material which does not dissolve in an electrolyte solution should be selected.

As the electrolyte solution in which the separator 324 is soaked, for example, a mixture in which lithium hexafluorophosphate (LiPF₆) is added to a mixed solution of ethylene carbonate (EC) and diethyl carbonate (DEC) may be used. Further, as the electrolyte, lithium chloride (LiCl), lithium fluoride (LiF), lithium perchlorate (LiClO₄), lithium fluoroborate (LiBF₄), lithium bis(trifluoromethanesulfonyl)imide (LiN(SO₂CF₃)₂), lithium bis(pentafluoroethanesulfonyl)imide (LiN(SO₂C₂F₅)₂), lithium trifluoromethansulfonate (LiCF₃SO₃), or the like can be used. Furthermore, in the case where an alkali metal ion other than a lithium ion is used, sodium chloride (NaCl), sodium fluoride (NaF), sodium perchlorate (NaClO₄), sodium fluoroborate (NaBF₄), potassium chloride (KCl), potassium fluoride (KF), potassium perchlorate (KClO₄), potassium fluoroborate (KBF₄), or the like can be used, one or more of which may be dissolved in a solvent.

Examples of the solvent include: cyclic carbonates such as propylene carbonate (PC), butylene carbonate (BC), and vinylene carbonate (VC); acyclic carbonates such as dimethyl carbonate (DMC), ethylmethyl carbonate (hereinafter abbreviated as EMC), methylpropyl carbonate (MPC), methylisobutyl carbonate (MIBC), and dipropyl carbonate (DPC); aliphatic carboxylic acid esters such as methyl formate, methyl acetate, methyl propionate, and ethyl propionate; γ-lactones such as γ-butyrolactone; acyclic ethers such as 1,2-dimethoxyethane (DME), 1,2-diethoxyethane (DEE), and ethoxymethoxy ethane (EME); cyclic ethers such as tetrahydrofuran and 2-methyltetrahydrofuran; dimethylsulfoxide; 1,3-dioxolane; alkyl phosphate esters such as trimethyl phosphate, triethyl phosphate, and trioctyl phosphate and fluorides thereof. These materials can be used either alone or in combination.

Note that the case where lithium ions are mainly included in the electrolyte solution is described in this embodiment; however, there is no limitation thereto and another alkali metal ion may be used.

As described above, a battery can be manufactured using the electrode described in Embodiments 1 and 2 as the positive electrode.

With the use of the structure described in this embodiment, a power storage device with large capacitance and excellent characteristics can be obtained.

### Embodiment 4

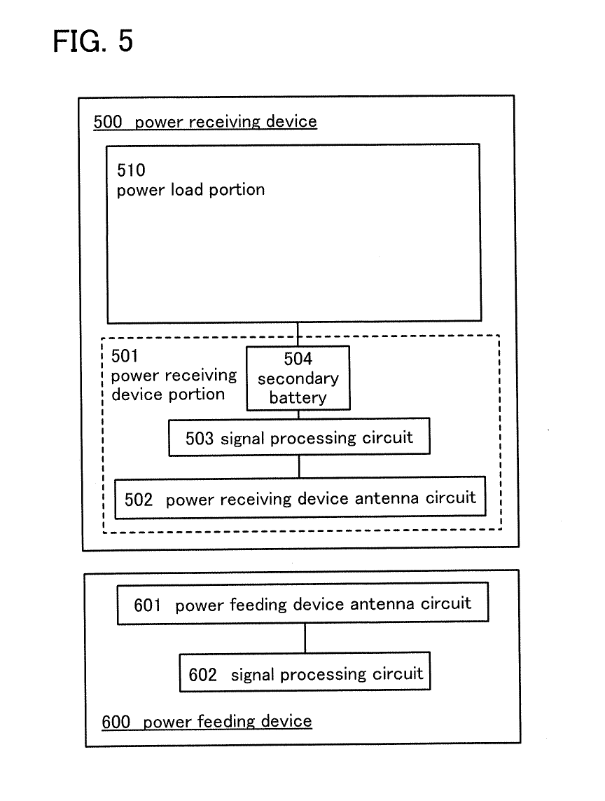

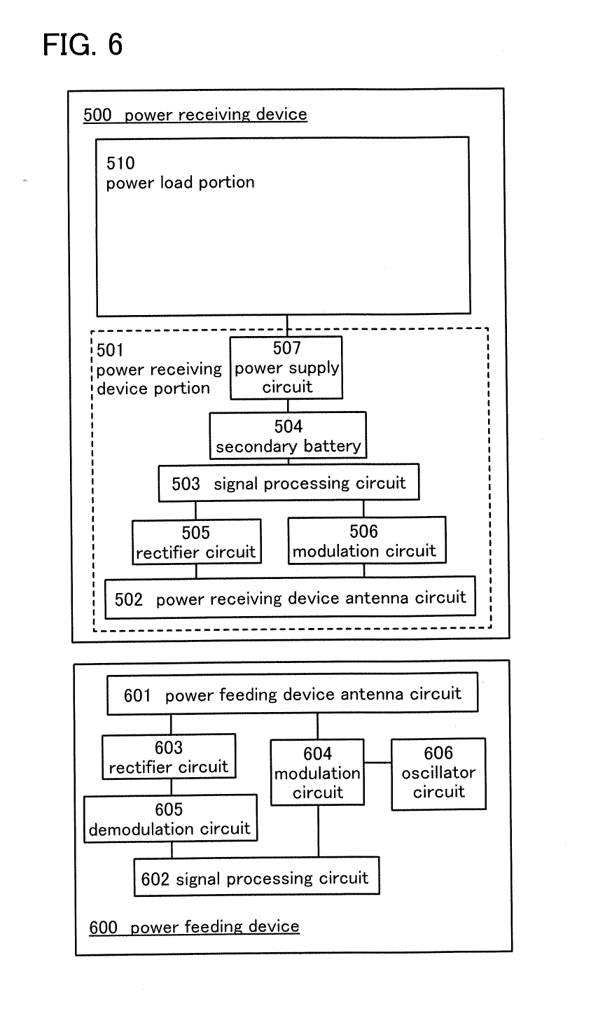

In this embodiment, an example in which the secondary battery according to one embodiment of the present invention is used in a wireless power feeding system (hereinafter referred to as an RF power feeding system) will be described with reference to block diagrams in FIG. 5 and FIG. 6. In each of the block diagrams, independent blocks show elements within a power receiving device and a power feeding device, which are classified according to their functions. However, it may be practically difficult to completely separate the elements according to their functions; in some cases, one element can involve a plurality of functions.

First, the RF power feeding system is described with reference to FIG. 5.

A power receiving device 500 is an electronic device or an electric propulsion vehicle which is driven by electric power supplied from a power feeding device 600, and can be applied to another device which is driven by electric power, as appropriate. Typical examples of the electronic device include cameras such as digital cameras or video cameras, digital photo frames, mobile phones (also referred to as cellular phones or cellular phone devices), portable game machines, portable information terminals, audio reproducing devices, display devices, computers, and the like. Typical examples of the electric propulsion vehicles include electric vehicles, hybrid vehicles, train vehicles, working vehicles, carts, wheelchairs, and the like. In addition, the power feeding device 600 has a function of supplying electric power to the power receiving device 500.

In FIG. 5, the power receiving device 500 includes a power receiving device portion 501 and a power load portion 510. The power receiving device portion 501 includes at least a power receiving device antenna circuit 502, a signal processing circuit 503, and a secondary battery 504. The power feeding device 600 includes a power feeding device antenna circuit 601 and a signal processing circuit 602.

The power receiving device antenna circuit 502 has a function of receiving a signal transmitted by the power feeding device antenna circuit 601 or transmitting a signal to the power feeding device antenna circuit 601. The signal processing circuit 503 processes a signal received by the power receiving device antenna circuit 502 and controls charging of the secondary battery 504 and supplying of electric power from the secondary battery 504 to the power load portion 510. The power load portion 510 is a driving portion which receives electric power from the secondary battery 504 and drives the power receiving device 500. Typical examples of the power load portion 510 include a motor, a driving circuit, and the like; however, another power load portion can be used as appropriate. The power feeding device antenna circuit 601 has a function of transmitting a signal to the power receiving device antenna circuit 502 or receiving a signal from the power receiving device antenna circuit 502. The signal processing circuit 602 controls operation of the power feeding device antenna circuit 601. That is, the signal processing circuit 602 can control the intensity, the frequency, or the like of a signal transmitted by the power feeding device antenna circuit 601.

The secondary battery according to one embodiment of the present invention is used as the secondary battery 504 included in the power receiving device 500 of the RF power feeding system.

With the use of the secondary battery according to one embodiment of the present invention in the RF power feeding system, the amount of power storage can be larger than that in a conventional secondary battery. Therefore, the time interval of the wireless power feeding can be longer (frequent power feeding can be omitted).

In addition, with the use of the secondary battery according to one embodiment of the present invention in the RF power feeding system, the power receiving device 500 can be formed to be compact and lightweight if the amount of power storage with which the power load portion 510 can be driven is the same as that in a conventional secondary battery. Therefore, the total cost can be reduced.

Next, another example of the RF power feeding system is described with reference to FIG. 6.

In FIG. 6, the power receiving device 500 includes the power receiving device portion 501 and the power load portion 510. The power receiving device portion 501 includes at least the power receiving device antenna circuit 502, the signal processing circuit 503, the secondary battery 504, a rectifier circuit 505, a modulation circuit 506, and a power supply circuit 507. The power feeding device 600 includes at least the power feeding device antenna circuit 601, the signal processing circuit 602, a rectifier circuit 603, a modulation circuit 604, a demodulation circuit 605, and an oscillator circuit 606.

The power receiving device antenna circuit 502 has a function of receiving a signal transmitted by the power feeding device antenna circuit 601 or transmitting a signal to the power feeding device antenna circuit 601. When the power receiving device antenna circuit 502 receives a signal transmitted by the power feeding device antenna circuit 601, the rectifier circuit 505 has a function of generating DC voltage from the signal received by the power receiving device antenna circuit 502. The signal processing circuit 503 has a function of processing a signal received by the power receiving device antenna circuit 502 and controlling charging of the secondary battery 504 and supplying of electric power from the secondary battery 504 to the power supply circuit 507. The power supply circuit 507 has a function of converting voltage stored by the secondary battery 504 into voltage needed for the power load portion. The modulation circuit 506 is used when a certain response is transmitted from the power receiving device 500 to the power feeding device 600.

With the power supply circuit 507, electric power supplied to the power load portion 510 can be controlled. Thus, overvoltage application to the power load portion 510 can be suppressed, and deterioration or breakdown of the power receiving device 500 can be reduced.

In addition, with the modulation circuit 506, a signal can be transmitted from the power receiving device 500 to the power feeding device 600. Therefore, when the amount of charged power in the power receiving device 500 is judged and a certain amount of power is charged, a signal is transmitted from the power receiving device 500 to the power feeding device 600 so that power feeding from the power feeding device 600 to the power receiving device 500 can be stopped. Thus, it is possible not to fully charge the secondary battery 504, so that the number of times of charging of the secondary battery 504 can be increased.

The power feeding device antenna circuit 601 has a function of transmitting a signal to the power receiving device antenna circuit 502 or receiving a signal from the power receiving device antenna circuit 502. When a signal is transmitted to the power receiving device antenna circuit 502, the signal processing circuit 602 generates a signal which is transmitted to the power receiving device. The oscillator circuit 606 is a circuit which generates a signal with a constant frequency. The modulation circuit 604 has a function of applying voltage to the power feeding device antenna circuit 601 in accordance with the signal generated by the signal processing circuit 602 and the signal with a constant frequency generated by the oscillator circuit 606. Thus, a signal is output from the power feeding device antenna circuit 601. When a signal is received from the power receiving device antenna circuit 502, the rectifier circuit 603 rectifies the received signal. The demodulation circuit 605 extracts the signal transmitted from the power receiving device 500 to the power feeding device 600 from signals rectified by the rectifier circuit 603. The signal processing circuit 602 has a function of analyzing the signal extracted by the demodulation circuit 605.

Note that any circuit may be provided between circuits as long as the RF power feeding can be performed. For example, after the power receiving device 500 receives an electromagnetic wave and the rectifier circuit 505 generates DC voltage, constant voltage may be generated by a circuit such as a DC-DC converter or a regulator. Thus, overvoltage application to the inside of the power receiving device can be suppressed.

The secondary battery according to one embodiment of the present invention is used as the secondary battery 504 included in the power receiving device 500 of the RF power feeding system.

With the use of the secondary battery according to one embodiment of the present invention in the RF power feeding system, the amount of power storage can be larger than that in a conventional secondary battery. Therefore, the time interval of the wireless power feeding can be longer (frequent power feeding can be omitted).

In addition, with the use of the secondary battery according to one embodiment of the present invention in the RF power feeding system, the power receiving device 500 can be formed to be compact and lightweight if the amount of power storage with which the power load portion 510 can be driven is the same as that in a conventional secondary battery. Therefore, the total cost can be reduced.

Note that in the case where the secondary battery according to one embodiment of the present invention is used in the RF power feeding system and the power receiving device antenna circuit 502 and the secondary battery 504 overlap with each other, it is preferable that the impedance of the power receiving device antenna circuit 502 be not changed by deformation of the secondary battery 504 due to charge and discharge of the secondary battery 504. When the impedance of the antenna is changed, in some cases, electric power is not supplied sufficiently. For example, the secondary battery 504 may be placed in a battery pack formed using metal or ceramics. Note that in that case, the power receiving device antenna circuit 502 and the battery pack are preferably separated from each other by several tens of micrometers or more.

In this embodiment, the charging signal has no limitation on its frequency and may have any band of frequency as long as electric power can be transmitted. For example, the charging signal may have any of an LF band of 135 kHz (long wave), an HF band of 13.56 MHz, a UHF band of 900 MHz to 1 GHz, and a microwave band of 2.45 GHz.

A signal transmission method may be selected as appropriate from various methods including an electromagnetic coupling method, an electromagnetic induction method, a resonance method, and a microwave method. In one embodiment of the present invention, in order to prevent energy loss due to foreign substances containing moisture, such as rain and mud, the electromagnetic induction method or the resonance method using a low frequency band, more specifically, frequencies of a short wave of 3 MHz to 30 MHz, a medium wave of 300 kHz to 3 MHz, a long wave of 30 kHz to 300 kHz, or a very-low frequency wave of 3 kHz to 30 kHz, may be used.

This embodiment can be implemented in combination with any of the above embodiments.

This application is based on Japanese Patent Application serial no. 2010-122907 filed with Japan Patent Office on May 28, 2010, the entire contents of which are hereby incorporated by reference.

What is claimed is:

1. A power storage device comprising:
a current collector; and
a first layer over the current collector, the first layer comprising:
a second layer including carbon; and
an active material layer including a plurality of particulate crystals, wherein the second layer and the active material layer are stacked n times,
wherein the active material layer contains a lithium metal oxide, and
wherein n is a natural number more than or equal to 2.

2. The power storage device according to claim 1, further comprising a third layer including carbon over the first layer.

3. The power storage device according to claim 1, wherein the n is more than or equal to 2 and less than or equal to 10.

4. The power storage device according to claim 1, wherein the lithium metal oxide is any one of LiFePO₄, LiMnPO₄, LiNiPO₄, and LiCrPO₄.

5. The power storage device according to claim 1, wherein the plurality of particulate crystals included in the active material layer is formed by heat treatment.

6. A power storage device comprising:
a current collector; and
a first layer over the current collector, the first layer comprising:
a second layer including carbon; and
an active material layer including a plurality of particulate crystals, wherein the second layer and the active material layer are stacked n times in this order,
wherein the active material layer contains a lithium metal oxide, and
wherein n is a natural number more than or equal to 2.

7. The power storage device according to claim 6, further comprising a third layer including carbon over the first layer.

8. The power storage device according to claim 6, wherein the n is more than or equal to 2 and less than or equal to 10.

9. The power storage device according to claim 6, wherein the lithium metal oxide is any one of LiFePO₄, LiMnPO₄, LiNiPO₄, and LiCrPO₄.

10. The power storage device according to claim 6, wherein the plurality of particulate crystals included in the active material layer is formed by heat treatment.

11. A power storage device comprising:
a current collector; and
a first layer over the current collector, the first layer comprising:
a second layer including carbon; and
an active material layer including a plurality of particulate crystals, wherein the active material layer and the second layer are stacked n times in this order,
wherein the active material layer contains a lithium metal oxide, and
wherein n is a natural number more than or equal to 2.

12. The power storage device according to claim 11, wherein the n is more than or equal to 2 and less than or equal to 10.

13. The power storage device according to claim 11, wherein the lithium metal oxide is any one of LiFePO₄, LiMnPO₄, LiNiPO₄, and LiCrPO₄.

14. The power storage device according to claim 11, wherein the plurality of particulate crystals included in the active material layer is formed by heat treatment.

15. A method for manufacturing a power storage device, comprising the steps of:
forming a current collector;
forming a first stacked layer over the current collector, wherein the first stacked layer comprises a first layer including carbon and a first active material layer including a lithium metal oxide;
forming a second stacked layer over the first stacked layer, wherein the second stacked layer comprises a second layer including carbon and a second active material layer including the lithium metal oxide; and
performing heat treatment to crystallize the lithium metal oxide,
wherein each of the first active material layer and the second active material layer is formed by a sputtering method.

16. The method according to claim 15, wherein the lithium metal oxide is any one of LiFePO₄, LiMnPO₄, LiNiPO₄, and LiCrPO₄.

17. The method according to claim 15, wherein each of the first layer and the second layer is formed by an evaporation method.

18. The method according to claim 15,
wherein the first layer and the first active material layer are stacked in this order, and
wherein the second layer and the second active material layer are stacked in this order.

19. The method according to claim 15,
wherein the first active material layer and the first layer are stacked in this order, and
wherein the second active material layer and the second layer are stacked in this order.

20. The method according to claim 15, further comprising the step of forming a third stacked layer over the second stacked layer, wherein the third stacked layer comprises a third layer including carbon and a third active material layer including the lithium metal oxide,
wherein the step of performing heat treatment is after forming the third stacked layer.
